(19) United States
(12) Patent Application Publication
(10) Pub. No.: US 2011/0121803 A1
(43) Pub. Date: May 26, 2011

(54) SEMICONDUCTOR DEVICE AND DC-DC CONVERTER

(75) Inventors: Kazutoshi Nakamura, Kanagawa-ken (JP); Koichi Endo, Hyogo-ken (JP)

(73) Assignee: Kabushiki Kaisha Toshiba, Tokyo (JP)

(21) Appl. No.: 12/885,394

(22) Filed: Sep. 17, 2010

(30) Foreign Application Priority Data
Nov. 26, 2009 (JP) 2009-268618

(51) Int. Cl. G05F 1/08; H01L 27/092

(52) U.S. Cl. 323/282; 257/369; 257/E27.062

(57) ABSTRACT

According to one embodiment, a semiconductor device includes a base layer of a second conductivity type, a device isolation layer, a control electrode, a high dielectric layer, a first main electrode, and a second main electrode. The base layer includes a source region of a first conductivity type and a drain region of the first conductivity type. The source region and the drain region are selectively formed on a surface of the base layer. The device isolation layer is provided in the base layer to be extended in a direction from the source region to the drain region. The control electrode is provided on a top side of the device isolation layer to control a current passage between the source region and the drain region. The high dielectric layer is arranged in at least a part on a top side of the base layer or in at least a part in the device isolation layer. The high dielectric layer has a higher dielectric constant than a dielectric constant of the device isolation layer. The first main electrode is connected to the source region. The second main electrode is connected to the drain region.

### CROSS-REFERENCE TO RELATED APPLICATIONS

This application is based upon and claims the benefit of priority from the prior Japanese Patent Application No. 2009-268618, filed on Nov. 26, 2009; the entire contents of which are incorporated herein by reference.

### FIELD

Embodiments described herein relate generally to a semiconductor device and a DC-DC converter.

### BACKGROUND

In recent years, there is a tendency in which a complicated system and a power device are integrated together by integrating devices and the power device. Devices and the power device are formed by a microprocess. Even in a case where devices are combined with a power device, conditions of the microprocess are required not to be largely changed. For example, because characteristics of a fine CMOS device are affected, a heat process and the like should desirably be changed as little as possible. Particularly, a shorter heat history is more desirable for the recent microprocesses, because a p-n junction is formed in a position shallow from a substrate surface.

Recently, in the microprocesses, a technology has been reported in which a thick gate oxide film is formed without adding any process (e.g., refer to J. Sonsky, G. Doornnbos, A. Heringa, M. van Duuren, J. Perez-Gonzalez, “Towards universal and voltage-scalable high gate and drain-voltage MOSFETs in CMOS”, Proceedings of ISPSD 2009 IEEE, P. 315-318).

The device has a structure in which STIs (Shallow Trench Isolations), i.e., device isolation layers, are formed in a stripe configuration and a gate electrode is disposed on a STI. In other words, the structure has no gate disposed on a semiconductor layer.

Because there is a distance in a plane between the gate electrode disposed on the STI and a P-well region between the STIs, a thick gate oxide film is formed between the gate electrode and the P-well region. Thereby, the gate oxide film having a high breakdown voltage is provided. However, the reality is that the reduction in the ON resistance per a unit area of the power device remains yet to be improved.

### BRIEF DESCRIPTION OF THE DRAWINGS

FIGS. 1A to 1C show a semiconductor device according to an embodiment, where FIG. 1A is a main part lateral cross-sectional view of the semiconductor device as taken along A-B horizontal plane of FIGS. 1B and 1C and viewed from above, FIG. 1B is an X-X′ cross-sectional view of FIG. 1A, and FIG. 1C is a Y-Y′ cross-sectional view of FIG. 1A;

FIGS. 2A to 2C show main part circuit diagrams of a semiconductor device and a DC-DC converter using the semiconductor device, where FIG. 2A is a main part circuit diagram of the DC-DC converter, FIG. 2B is a main part circuit diagram of the semiconductor device and a control circuit for controlling the semiconductor device, and FIG. 2C is a main part circuit of the control circuit;

FIGS. 3A and 3B show diagrams for explaining operations of the semiconductor device, where FIG. 3A shows an X-X′ cross-sectional view of the semiconductor device according to the embodiment, and FIG. 3B shows an X-X′ cross-sectional view and a Y-Y′ cross-sectional view of a semiconductor device according to a comparative example;

FIGS. 4A to 4C are main part cross-sectional views of a process of manufacturing a CMOS and a semiconductor device, where part (a) shows main part cross-sectional views of a process of manufacturing a switching element in the CMOS, part (β) shows X-X′ cross-sectional views of a process of manufacturing the semiconductor device, and part (γ) shows Y-Y′ cross-sectional views of the process of manufacturing the semiconductor device;

FIGS. 5A and 5B are main part cross-sectional views of a process of manufacturing a CMOS and a semiconductor device, where part (α) shows main part cross-sectional views of a process of manufacturing a switching element in the CMOS, part (β) shows X-X′ cross-sectional views of a process of manufacturing the semiconductor device, part (γ) shows Y-Y′ cross-sectional views of the process of manufacturing the semiconductor device, and FIGS. 5A and 5B are diagrams of a process of forming a sidewall protecting film;

FIGS. 6A and 6B are main part cross-sectional views of a process of manufacturing a CMOS and a semiconductor device, where part (α) shows main part cross-sectional views of a process of manufacturing a switching element in the CMOS, part (β) shows X-X′ cross-sectional views of a process of manufacturing the semiconductor device, part (γ) shows Y-Y′ cross-sectional views of the process of manufacturing the semiconductor device, FIG. 6A is a diagram of a process of forming a sidewall protecting film, and FIG. 6B is a diagram of a process of forming a source region and a drain region;

FIGS. 7A and 7B show semiconductor devices of first and second variation examples of the embodiment, where FIG. 7A is a main part cross-sectional view of the semiconductor device of the first variation example, and FIG. 7B is a main part cross-sectional view of the semiconductor device of the second variation example;

FIGS. 8A and 8B show semiconductor devices of third and fourth variation examples of the embodiment, where FIG. 8A is a main part cross-sectional view of the semiconductor device of the third variation example, and FIG. 8B is a main part cross-sectional view of the semiconductor device of the fourth variation example;

FIGS. 9A and 9B show a semiconductor device of a fifth variation example of the embodiment, where FIG. 9A is a main part lateral cross-sectional view of the semiconductor device of the fifth variation example as taken along A-B horizontal plane of FIG. 9B and viewed from above, and FIG. 9B is a Y-Y′ cross-sectional view of FIG. 9A;

FIGS. 10A and 10B show a semiconductor device of a sixth variation example of the embodiment, where FIG. 10A is a main part lateral cross-sectional view of the semiconductor device of the sixth variation example as taken along A-B horizontal plane of FIG. 10B and viewed from above, and FIG. 10B is a Y-Y′ cross-sectional view of FIG. 10A;

FIGS. 11A to 11C show a semiconductor device of a seventh variation example of the embodiment, where FIG. 11A is a main part lateral cross-sectional view of the semiconductor device of the seventh variation example as taken along A-B horizontal plane of FIGS. 11B and 11C and viewed from above, FIG. 11B is an X-X′ cross-sectional view of FIG. 11A, and FIG. 11C is a Y-Y′ cross-sectional view; and

FIGS. 12A and 12B show a semiconductor device of a eighth variation example of the embodiment, where FIG. 12A is a main part lateral cross-sectional view of the semiconductor device of the eighth variation example as taken along A-B horizontal plane and viewed from above, and FIG. 12B is a Y-Y′ cross-sectional view of FIG. 12A.

### DETAILED DESCRIPTION

In general, according to one embodiment, a semiconductor device includes a base layer of a second conductivity type, a device isolation layer, a control electrode, a high dielectric layer, a first main electrode, and a second main electrode. The base layer includes a source region of a first conductivity type and a drain region of the first conductivity type. The source region and the drain region are selectively formed on a surface of the base layer. The device isolation layer is provided in the base layer to extend in a direction from the source region to the drain region. The control electrode is provided on a top side of the device isolation layer to control a current passage between the source region and the drain region. The high dielectric layer is arranged in at least a part on a top side of the base layer or in at least a part in the device isolation layer. The high dielectric layer has a higher dielectric constant than a dielectric constant of the device isolation layer. The first main electrode is connected to the source region. The second main electrode is connected to the drain region.

According to another embodiment, a DC-DC converter includes a high-side switching element, a low-side switching element, the above-described semiconductor device, an inductor, and a capacitor. The low-side switching element is connected to the high-side switching element in series. The semiconductor device serves as a driver circuit for controlling the high-side switching element and the low-side switching element. The inductor has one end side connected between the high-side switching element and the low-side switching element. The capacitor is connected to one other end side of the inductor.

Embodiments of a semiconductor device will now be described with reference to the drawings.

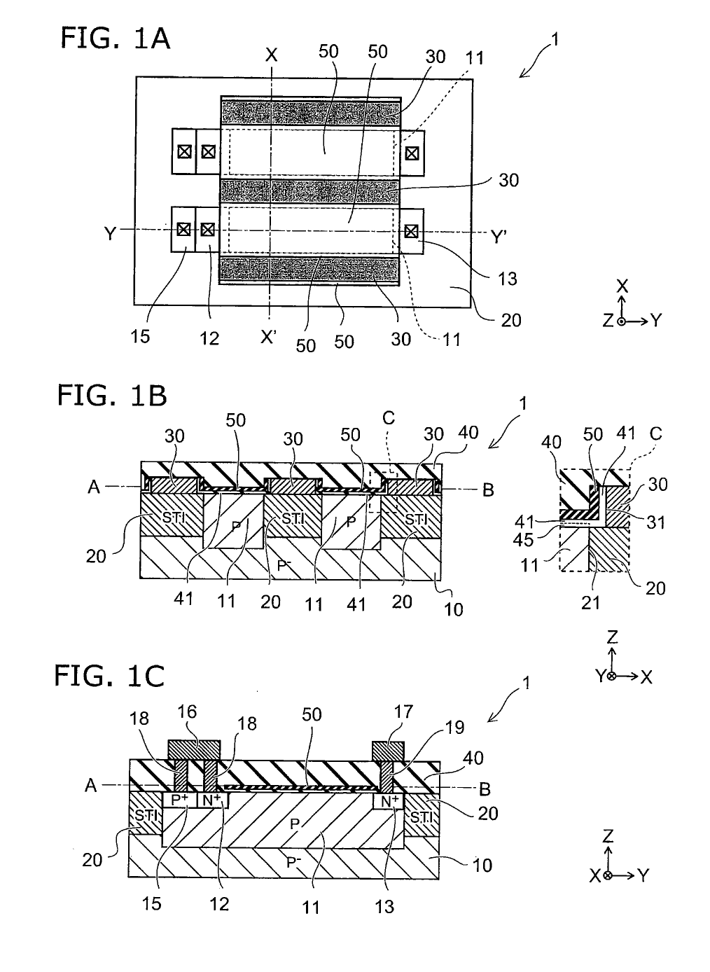

FIGS. 1A to 1C show a semiconductor device according to an embodiment. FIG. 1A is a main part lateral cross-sectional view of the semiconductor device as taken along A-B horizontal plane of FIGS. 1B and 1C and viewed from above. FIG. 1B is an X-X′ cross-sectional view of FIG. 1A. FIG. 1C is a Y-Y′ cross-sectional view of FIG. 1A. However, an interlayer insulating film 40 shown in FIGS. 1B and 1C is excluded from FIG. 1A.

A semiconductor device 1 includes, for example, silicon (Si) or the like as its main component. The semiconductor device 1 includes: a semiconductor layer 10 of P⁻-type as a second conductivity type; a base layer 11 of P-type selectively formed on the semiconductor layer 10 of P⁻-type; and a device isolation layer 20 (hereinafter referred to a STI 20) selectively provided in the base layer 11. In addition, a source region 12 of N⁺-type as a first conductivity type is selectively provided on the base layer 11. A drain region 13 of N⁺-type is selectively provided on the base layer 11 and spaced out from the source region 12. On the base layer 11, a contact region 15 of P⁺-type is adjacent to the source region 12. The semiconductor device 1 is an N-channel type MOS. The base layer 11 may be referred to as a well layer of the second conductivity type in some cases.

The STI 20, i.e., the device isolation layer, is an insulator, and includes, for example, silicon oxide (SiO₂) as its main component. The STIs 20 are provided in the base layer 11. The STIs 20 extend in a direction from the source region 12 to the drain region 13 (a Y direction in the drawings) in a stripe configuration. In addition, the STIs 20 are periodically arranged in a direction almost perpendicular to the direction in which the STIs 20 extend (an X direction in the drawings). Thereby, the base layer 11 between the neighboring STIs 20 extends almost in parallel to the STIs 20. Furthermore, a gate electrode 30 as a control electrode is provided on the top side of the STI 20 and controls current passages between the source region 12 and the drain region 13. Although FIGS. 1A to 1C illustrate three gate electrodes 30, the number of gate electrodes 30 is not limited thereto. Depending on the number of gate electrodes 30, the base layers 11, the source regions 12, the drain regions 13, and the like are arranged on the both sides of the respective gate electrodes 30.

Moreover, a portion C in FIG. 1B is shown on the right side of FIG. 1B. A sidewall 31 of the gate electrode 30 is not flush with a sidewall 21 of the STI 20, but is situated inside the STI 20. In the semiconductor device 1, a high dielectric layer 50 is provided in at least a part on the top side of the base layer 11 between the neighboring gate electrodes 30. FIGS. 1A to 1C show a state in which the high dielectric layer 50 is provided over the entire surface on the top side of the base layer 11.

For example, in the case where the high dielectric layer 50 is provided over the entire surface on the top side of the base layer 11, the high dielectric layer 50 is not only provided on the top side of the base layer 11, but also extends to the sidewall 31 of the gate electrode 30. Specifically, the high dielectric layer 50 is arranged adjacent to the sidewall 31 of the gate electrode 30 and to the base layer 11 between the STIs 20. The high dielectric layer 50 extends in the Y direction in the drawings. Furthermore, an oxide film 41 and an oxide film 45 are formed between the high dielectric layer 50 and the base layer 11. The oxide film 41 is formed between the high dielectric layer 50 and the gate electrode 30. Moreover, in the semiconductor device 1, the interlayer insulating layer 40 is provided on the top side of the base layer 11 and on the top side of the gate electrode 30 for the purpose of keeping insulation between vias and between wirings (not illustrated).

The material of the interlayer insulating layer 40, the oxide film 41, and the oxide film 45 are silicon oxide (SiO₂), for example. Thereby, the STI 20, the oxide film 41, the oxide film 45, and the interlayer insulating layer 40 exist between the gate electrode 30 and the base layer 11. Accordingly, a thick oxide film is interposed between the gate electrode 30 and the base layer 11. If this thick oxide film is taken as a gate oxide film of the semiconductor device 1, the semiconductor device 1 includes a gate oxide film having a high breakdown voltage. The relative dielectric constant of silicon oxide (SiO₂) is approximately 3.9, for example.

In addition, as the material of the high dielectric layer 50, a material having a higher dielectric constant than any of the STI 20, the interlayer insulating layer 40, and the oxide film 41 is selected. Therefore, capacitive coupling is facilitated. Capacitive coupling will be described later. For example, silicon nitride (Si₃N₄) is applicable to the material of the high dielectric layer 50. The relative dielectric constant of silicon nitride (Si₃N₄) is approximately 7.5. Instead, hafnium oxide (HfO₂) or the like may be used as the material of the high dielectric layer 50. Capacitive coupling is facilitated due to the high dielectric layer 50 when the semiconductor device 1 is in the ON state by arranging the high dielectric layer 50 having such a high relative dielectric constant. Thus, charges in high concentration are induced in a part of the surface or a part of the sidewall of the base layer 11 facing the gate electrode 30. This phenomenon will be described again in detail when operations of the semiconductor device 1 are described.

In addition, the above-described drain region 13, source region 12, and contact region 15 are selectively provided in a longitudinal end portion of the base layer 11. Furthermore, as a first main electrode, a source electrode 16 is electrically connected to the source region 12 and the contact region 15 through a via 18. A drain electrode 17, as a second main electrode, is electrically connected to the drain region 13 through a via 19. Moreover, the multiple gate electrodes 30 are connected to a common gate wiring (not illustrated). The multiple source electrodes 16 are connected together in parallel (not illustrated). The multiple drain electrodes 17 are connected together in parallel (not illustrated). Thereby, currents which flow in the respective base layers 11 merge, allowing a large current to flow in the semiconductor device 1. As described above, the semiconductor device 1 functions as a power MOS. Moreover, the ON and OFF of the semiconductor device 1 is controlled, for example, by a fine CMOS (Complementary Metal Oxide Semiconductor) formed on the same substrate as the semiconductor device 1.

Next, a DC-DC converter using the semiconductor device 1 as a driver circuit and a control circuit for driving the semiconductor device 1 will be described.

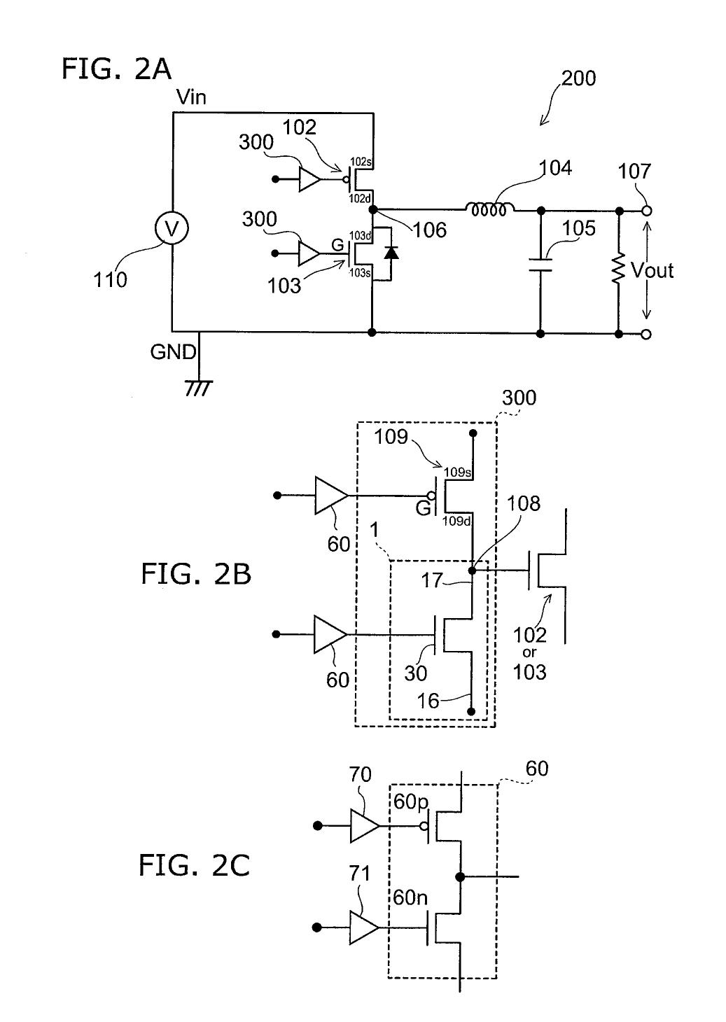

FIGS. 2A to 2C show main part circuit diagrams of a semiconductor device and a DC-DC converter using the semiconductor device. FIG. 2A is a main part circuit diagram of the DC-DC converter, FIG. 2B is a main part circuit diagram of the semiconductor device and the control circuit for controlling this semiconductor device, and FIG. 2C is a main part circuit of the control circuit.

A DC-DC converter 200 shown in FIG. 2A is a step-down DC-DC converter and includes driver circuits 300, a high-side switching element 102, a low-side switching element 103, an inductor 104, and a capacitor 105. The driver circuits 300 control the ON and OFF of the high-side switching element 102 and the low-side switching element 103.

The switching element 102 and the switching element 103 are connected together in series. One end side of the inductor 104 such as a coil is connected to a connecting point (node) 106 between a drain 102d of the switching element 102 and a drain 103d of the switching element 103, for example. A reference potential (e.g., a ground potential GND) is supplied to the other end side of the inductor 104 through the capacitor 105. A source 103s of the switching element 103 is connected to the reference potential (GND), and the reference potential is supplied to the source 103s as well. The other end of the inductor 104 is connected to an output terminal 107. An input voltage Vin is inputted into the source 102s of the switching element 102 from a power supply 110. The power supply 110 is provided between a source 102s of the switching element 102 and the reference potential (GND). An output voltage Vout to which the input voltage Vin is converted is outputted from the output terminal 107.

As shown in FIG. 2B, the semiconductor device 1 is built in the driver circuit 300. For example, a P-channel type switching element 109 is connected to the semiconductor device 1 serving as the switching element in series. A connecting point 108 between the drain electrode 17 of the semiconductor device 1 and a drain electrode 109d of the switching element 109 is connected to the gate electrode 30 of the switching element 102 or 103.

Furthermore, as shown in FIG. 2B, the gate electrode 30 of the semiconductor device 1 is connected to a CMOS 60 serving as the control circuit. The ON and OFF of the semiconductor device 1 is controlled on the basis of a control signal from the CMOS 60.

The CMOS 60 includes a switching element 60p formed of a P-channel type MOS and a switching element 60n formed of an N-channel type MOS as shown in FIG. 2C. The CMOS 60 is further controlled by control circuits 70 and 71 which are another CMOS. The driver circuits 300 including the semiconductor device 1 and the CMOSs 60 are provided on the same semiconductor layer 10. The semiconductor device 1 may be replaced with semiconductor devices 2 to 7 which will be described later. In addition, such driver circuits 300 and such CMOSs 60 may be built not only in the DC-DC converter, but also in a motor driver circuit or the like, for example (not illustrated).

Next, operations and effects of the semiconductor device 1 will be described.

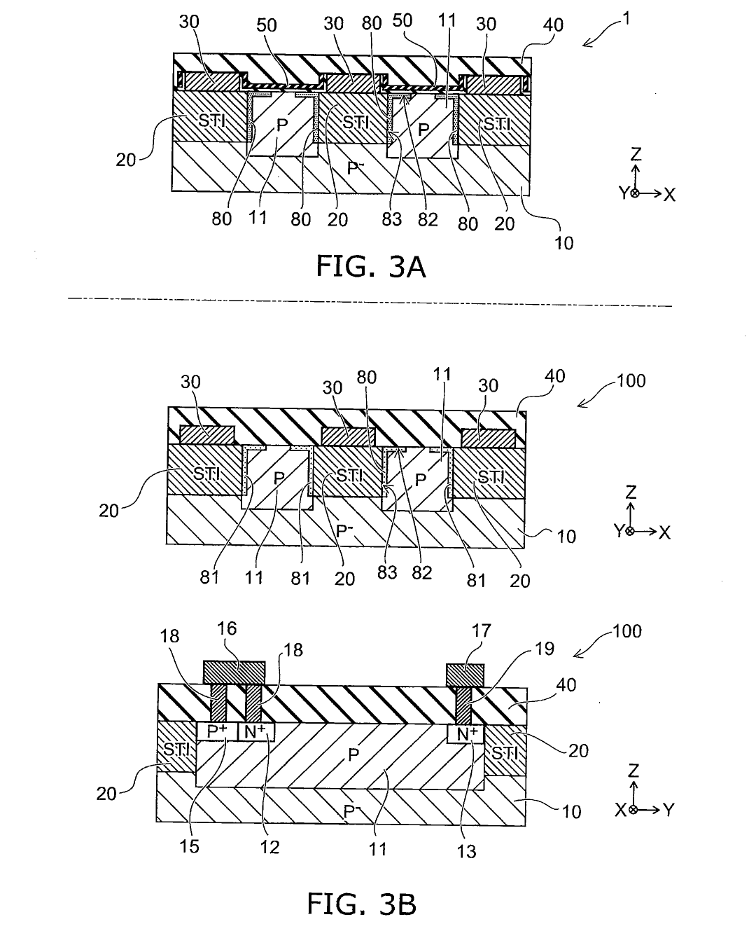

FIGS. 3A and 3B show diagrams for explaining operations of a semiconductor device. FIG. 3A is an X-X′ cross-sectional view of the semiconductor device according to the embodiment, and FIG. 3B is an X-X′ cross-sectional view and a Y-Y′ cross-sectional view of a semiconductor device according to a comparative example. The semiconductor device 100 is different from the semiconductor device 1 in not having the high dielectric layers 50 described above. The directions in FIGS. 3A and 3B correspond to the respective directions in FIG. 1B.

First of all, operations of a semiconductor device will be described by use of the semiconductor device 100. To begin with, a voltage which is not higher than a threshold voltage is applied between the gate electrode 30 and the source electrode 16, and a predetermined voltage is applied between the source electrode 16 and the drain electrode 17. At this time, a voltage is applied also between the gate electrode 30 and the drain electrode 17. Thus, a depletion layer extends from an interface between the STI 20 and the base layer 11. Because this depletion layer relaxes the electric field, the semiconductor device 100 maintains the high breakdown voltage.

Subsequently, a positive bias which is higher than the threshold voltage is applied to the gate electrode 30 in the semiconductor device 100. Thereby, an inversion layer 81 is generated in a part of a surface 82 or a part of a sidewall 83 of the base layer 11 which faces the gate electrode 30. Thereby, the semiconductor device 100 is turned on. By this, a current flows between the source electrode 16 and the drain electrode 17.

In this case, in the semiconductor device 100, the inversion layer 81 is formed mainly along the surface 82 or the sidewall 83 of the base layer 11. According to J. Sonsky, G. Doornnbos, A. Heringa, M. van Duuren, J. Perez-Gonzalez, “Towards universal and voltage-scalable high gate and drain-voltage MOSFETs in CMOS”, Proceedings of ISPSD 2009 IEEE, P. 315-318 described above, 58% of a current flowing between the source region 12 and the drain region 13 is distributed to the inversion layer 81 along the surface 82 of the base layer 11 while 39% of the current is distributed to the inversion layer 81 along the sidewall 83 of the base layer 11. Specifically, the current flowing along the surface 82 of the base layer 11 and the current flowing along the sidewall 83 of the base layer 11 mainly contribute to the flow of the current in the semiconductor device 100.

Similarly, when the semiconductor device 1 is turned on, an inversion layer 80 is formed mainly along the surface 82 or the sidewall 83 of the base layer 11, and a current accordingly flows between the source region 12 and the drain region 13. However, because the high dielectric layer 50 is arranged on the top side of the base layer 11 in the semiconductor device 1, the density of charges induced in the inversion layer 80 is high as compared with the semiconductor device 100. The reason for this is that, in the semiconductor device 1, the provision of the high dielectric layer 50 facilitates the capacitive couplings, and charges are accordingly induced in the surface 83 or the sidewall 83 of the base layer 11 to a large extent. For example, in FIGS. 3A and 3B, the degree of the density of charges generated in the inversion layers 80 and 81 is shown by shading. The darker shading indicates the higher charge density.

The high dielectric layer 50 is formed also on the sidewall 31 side of the gate electrode 30 as well. For this reason, the nearer to the gate electrode 30, the higher the charge density in the inversion layer 80 is.

Here, if silicon nitride (Si₃N₄) is used as the material of the high dielectric layer 50, the relative dielectric constant of the high dielectric layer 50 is almost twice the relative dielectric constant of silicon oxide (SiO₂) which is the material of the STI 20. Accordingly, in a case where the high dielectric layer 50 is interposed between the gate electrode 30 and the base layer 11, the density of charges induced in the inversion layer 80 of the base layer 11 increases. As a result, the ON resistance between the source region 12 and the drain region 13 (hereinafter referred to simply as an ON resistance) is reduced in the semiconductor device 1 as compared with the ON resistance in the semiconductor device 100.

Furthermore, even in a case where the high dielectric layer 50 is arranged in at least a part on the top side of the base layer 11, the high dielectric layer 50 can facilitate the capacitive coupling. For this reason, in the semiconductor device 1, it is sufficient that the high dielectric layer 50 is provided in at least a part on the top side of the base layer 11. In particular, because the intensity of the electric field is in inverse proportion to the distance from the gate electrode 30, charges produced in a vicinity of the gate electrode 30 mainly contributes to the reduction of the ON resistance. For this reason, it is desirable that the high dielectric layer 50 exists in the vicinity of the gate electrode 30.

No high dielectric layer 50 is provided in the semiconductor device 100 of the comparative example. For this reason, when the semiconductor device 100 is turned on, the electric fields are apt to locally concentrate in an end portion of the gate electrode 30. As a result, the density of charges in the inversion layer 81 becomes small as compared with the semiconductor device 1. Accordingly, the ON resistance per a unit area is larger in the semiconductor device 100 than in the semiconductor device 1. Increasing a channel width is one method for obtaining a desired ON resistance in this semiconductor device 100, but causes to increase the element size. For this reason, a structure which includes the high dielectric layers 50 as in the case of the semiconductor device 1 is preferable.

Next, a method for manufacturing the semiconductor device 1 will be described.

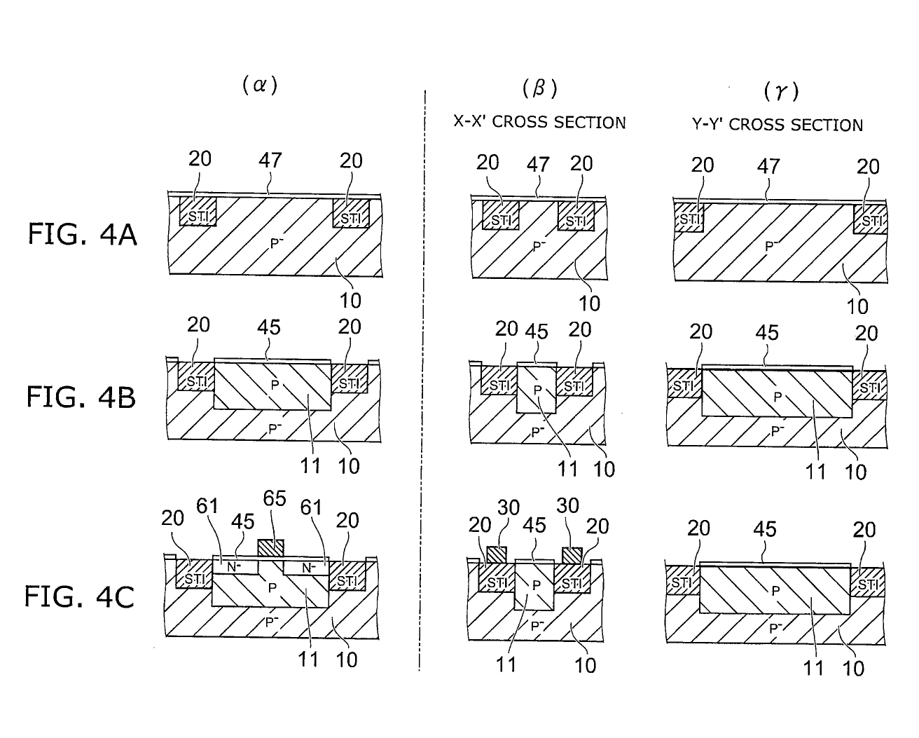

FIG. 4A to FIG. 6B are main part cross-sectional views for explaining the process of manufacturing a semiconductor device. Part (α) in FIG. 4A to FIG. 6B shows a process of manufacturing the N-channel type switching element 60n, as an example, in the CMOS built in the control circuit. As for the process of manufacturing the semiconductor device 1, part (β) shows the above-described X-X′ cross sections, and part (γ) shows the above-described Y-Y′ cross sections.

First of all, FIGS. 4A to 4C are the main part cross-sectional views of the process of manufacturing the CMOS and the semiconductor device. Part (α) shows main part cross-sectional views of a process of manufacturing the switching element in the CMOS. Part (β) shows X-X′ cross-sectional views of the process of manufacturing the semiconductor device. Part (γ) shows Y-Y′ cross-sectional views of the process of manufacturing the semiconductor device. In addition, FIG. 4A shows diagrams of a process of forming device isolation layers. FIG. 4B shows diagrams of a process of forming a base layer. FIG. 4C shows diagrams of a process of forming a gate oxide film, gate electrodes, and LDD (Lightly Doped Drain) regions.

As shown in FIG. 4A, the STIs 20 are formed in the semiconductor layer 10 of P⁻-type by a burying method. Subsequently, a buffer oxide film 47 to be used for ion plating implantation is formed on the semiconductor layer 10 and the STIs 20. The buffer oxide film 47 is formed by a thermal oxidation method and a low-pressure CVD method. Silicon oxide (SiO₂) or the like is selected as the material of the buffer oxide film 47. Thereafter, as shown in FIG. 4B, the well-shaped base layer 11 is formed between the neighboring STIs 20. Afterward, the buffer oxide film 47 is removed, and the oxide film 45 to become the gate oxide film of the switching element 60n is formed. The oxide film 45 is formed by a thermal oxidation method, a low-pressure CVD method, and the like. Silicon oxide (SiO₂), silicon oxynitride (SiON), silicon nitride (Si₃N₄), tantalum oxide (Ta₂O₅), or the like is selected as the material of the oxide film 45.

Next, as shown in FIG. 4C, the column-shaped gate electrodes 30 and 65 are formed through the oxide film 45. The patterning of the gate electrodes 30 and 65 is performed using a photolithography method, an X-ray lithography method, an electron-beam lithography method, a reactive ion etching (RIE) method, or the like. The material of the gate electrodes 30 and 65 is polysilicon, tungsten (W), or the like, for example. In a case where tungsten is used as the material of the gate electrodes 30 and 65, a barrier layer of titanium nitride (TiN) or tungsten nitride (WN) may be provided. In a region (α) for forming the N-channel type switching element 60n of the CMOS, the N⁻ regions (Lightly Doped Drain regions) 61 are selectively formed in the base layer 11 by an ion implantation method.

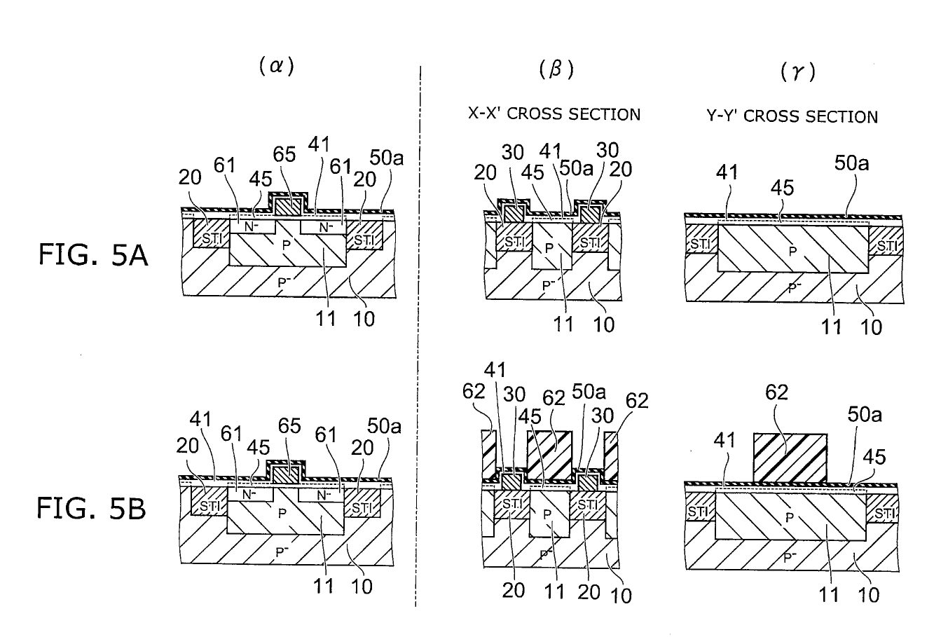

Next, FIGS. 5A and 5B show main part cross-sectional views of the process of manufacturing the CMOS and the semiconductor device. Part (α) shows main part cross-sectional views of the process of manufacturing the switching element in the CMOS. Part (β) shows X-X′ cross-sectional views of the process of manufacturing the semiconductor device. Part (γ) shows Y-Y′ cross-sectional views of the process of manufacturing the semiconductor device. FIGS. 5A and 5B are diagrams of a process of forming a sidewall protecting film.

As shown in FIG. 5A, the oxide film 41 made of silicon oxide (SiO₂) or the like and a nitride film 50a made of silicon nitride (Si₃O₄) or the like are sequentially formed on the periphery of the oxide film 45 and the gate electrodes 30 and 65 by a low-pressure CVD method. Subsequently, as shown in FIG. 5B, a resist 62 is patterned in regions (β) and (γ) for forming the semiconductor device 1. For example, by a photolithography method or the like, the resist 62 is selectively formed in the base layer 11 in a region for forming the semiconductor device 1. At this time, the oxide film 41 and the nitride film 50a in the vicinity of the sidewall of the gate electrode 30 are exposed to the outside. Furthermore, a region in which the source region 12, the drain region 13, and the contact region 15 of the semiconductor device are to be formed is exposed to the outside.

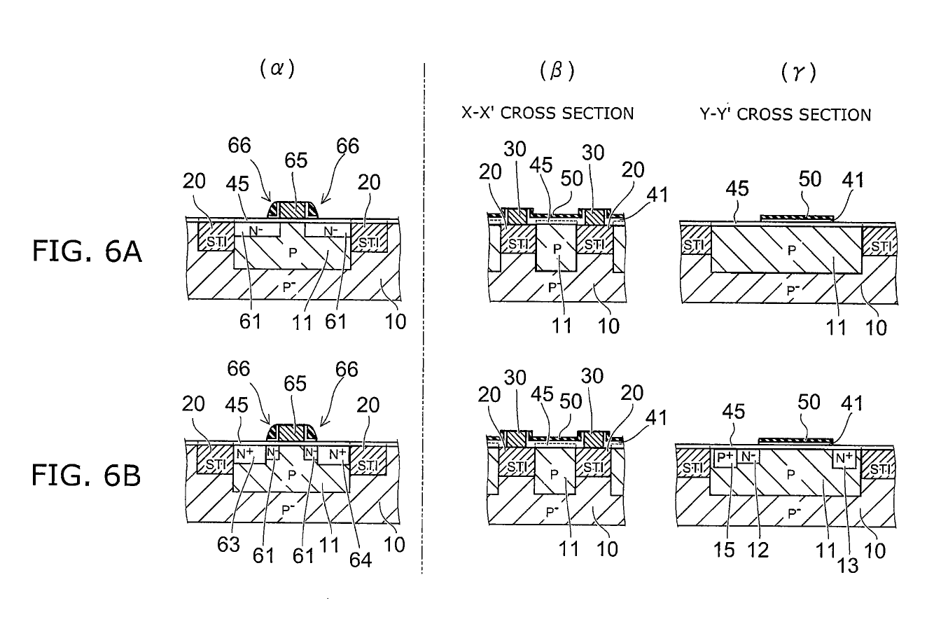

Next, FIGS. 6A and 6B show main part cross-sectional views of the process of manufacturing the CMOS and the semiconductor device. Part (α) shows main part cross-sectional views of the process of manufacturing the switching element in the CMOS. Part (β) shows X-X′ cross-sectional views of the process of manufacturing the semiconductor device. Part (γ) shows Y-Y′ cross-sectional views of the process of manufacturing the semiconductor device. FIG. 6A shows diagrams of the process of forming sidewall protecting films.

FIG. 6B shows diagrams of a process of forming a source region and a drain region. As shown in FIG. 6A, anisotropic etching (e.g., RIE or the like) is performed on the oxide film 41 and the nitride film 50a. Subsequently, the above-described resist 62 is removed. Thereby, the oxide film 41 and the nitride film 50a remain on the sidewall of the gate electrode 65 because this sidewall serves as a mask. Accordingly, a sidewall protecting film 66 including the oxide film and the nitride film is formed on the sidewall of the gate electrode 65. On the other hand, in the regions (β) and (γ) for forming the semiconductor device 1, the nitride film 50a on the base layer 11 between the STIs 20 is left, and the above-described high dielectric layer 50 is formed.

Next, in the region (α) for forming the N-channel type switching element 60n of the CMOS, a source region 63 of N⁺-type and a drain region 64 of N⁺-type are formed by an ion implantation method so as to be adjacent to the N⁻ region 61. Furthermore, in the regions (β) and (γ) for forming the semiconductor device 1, the source region 12, the drain region 13, and the contact region 15 are formed by an ion implantation method. This state is shown in FIG. 6B. Thereafter, in each element, the oxide film 45 on the source regions 12 and 63, the drain regions 13 and 64 and the contact regions 15 are removed; the source electrodes are connected to the respective source regions; and the drain electrodes are connected to the respective drain regions (not illustrated). Through such a method, the semiconductor device 1 and the CMOS are formed.

In this manufacturing process, the CMOS and the semiconductor device 1 are formed in parallel. For this reason, the high dielectric layers 50 and the sidewall protecting films 66 can be formed simultaneously. Thereby, the specialized process of forming only the high dielectric layers 50 is not necessary. Accordingly, in a case where the CMOS has a fine structure in which the nodes are as fine as approximately 65 nm, even if the semiconductor device 1 is mixedly mounted in the CMOS forming process, a large process change is not required. As a result, the semiconductor device 1 can be manufactured without changing the heat history of the CMOS.

Next, variation examples of the semiconductor device according to the invention will be described. In the following descriptions, similar members are marked with like reference numerals, and a detailed description is omitted as appropriate.

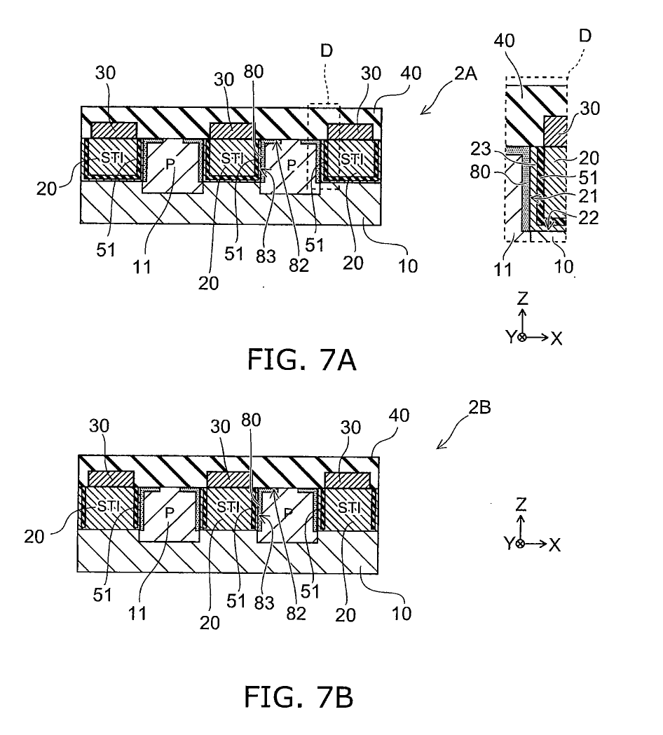

FIGS. 7A and 7B show semiconductor devices of first and second variation examples of the embodiment. FIG. 7A is a main part cross-sectional view of the semiconductor device of the first variation example. FIG. 7B is a main part cross-sectional view of the semiconductor device of the second variation example. FIGS. 7A and 7B show the main part cross-sectional views of semiconductor device 2 taken in a direction almost perpendicular to a direction in which the base layer 11 extends. In addition, a portion D in FIG. 7A is shown on the right side of FIG. 7A.

In a semiconductor device 2A which is the first variation example shown in FIG. 7A, a high dielectric layer 51 is provided in at least a part in the STI 20.

For example, FIG. 7A shows a state in which the high dielectric layer 51 is provided along the sidewall 21 and a bottom surface 22 of the STI 20. An oxide film 23 is interposed between the high dielectric layer 51 and the base layer 11. The material of the oxide film 23 is the same as that of the STI 20. In addition, the material of the high dielectric layer 51 is the same as that of the above-described high dielectric layer 50. The high dielectric layer 51 extends adjacent to the base layer 11 and along the sidewall 21 and the bottom surface 22 of the STI 20 in the Y direction in the drawing.

When the semiconductor device 2A with such a structure is turned on, the inversion layer 80 is formed mainly along the surface 82 or the sidewall 83 of the base layer 11. In particular, in the semiconductor device 2A, charges are induced on the sidewall 83 of the base layer 11 to a large extent, because the high dielectric layer 51 is arranged along the sidewall 21 and the bottom surface 22 of the STI 20. Accordingly, the ON resistance per a unit area is lower in the semiconductor device 2A than in the semiconductor device 100.

In addition, FIG. 7B shows a semiconductor device 2B as the second variation example.

In the semiconductor device 2B, the high dielectric layer 51 is arranged along only the sidewall 21 of the STI 20. In such a case as well, the above-described capacitive coupling can be facilitated, and the inversion layer 80 with a high density of charges can be formed. Specifically, it is sufficient that the high dielectric layer 51 is provided in at least a part in the STI 20.

In particular, the STI 20 needs to be a layer for isolating its neighboring elements. For this reason, if the inversion layer is excessively induced in the base layer 11 which faces the bottom surface 22 of the STI 20, the neighboring elements are likely to be electrically connected together through the inversion layer. In this case, the STI 20 is incapable of electrically isolating the neighboring elements. With this taken into consideration, in the semiconductor device 2B, the isolation between the neighboring elements is secured by forming the high dielectric layer 51 along only the sidewall 21. In addition, the ON resistance per a unit area is lower in the semiconductor device 2B than in the semiconductor device 100.

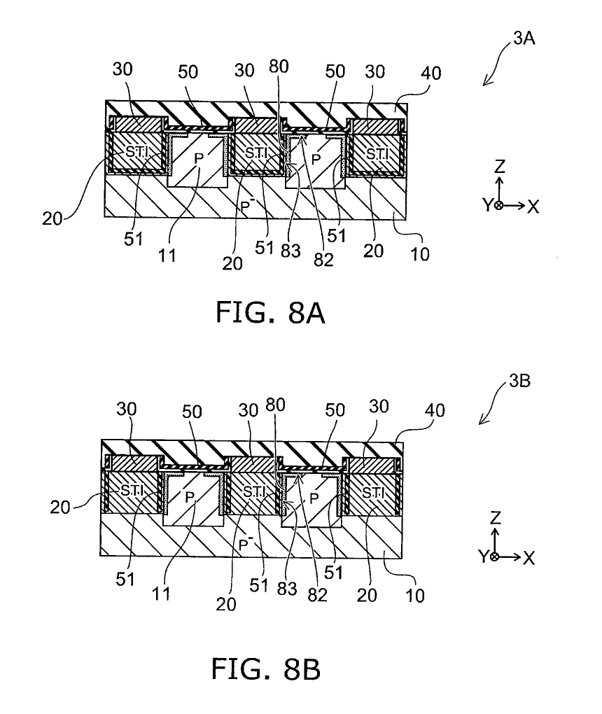

FIGS. 8A and 8B show semiconductor devices of third and fourth variation examples of the embodiment. FIG. 8A is a main part cross-sectional view of the semiconductor device of the third variation example. FIG. 8B is a main part cross-sectional view of the semiconductor device of the fourth variation example. FIGS. 8A and 8B show the main part cross-sectional views of the semiconductor device 3 taken in the direction almost perpendicular to the direction in which the base layers 11 extend.

In a semiconductor device 3A which is the third variation example shown in FIG. 8A, the high dielectric layer 50 is provided in at least a part on the top side of the base layer 11, and the high dielectric layer 51 is further provided in at least a part in the STI 20.

When the semiconductor device 3A with such a structure is turned on, the inversion layer 80 is formed mainly along the surface 82 or the sidewall 83 of the base layer 11. Charges are induced on the surface 82 and the sidewall 83 of the base layer 11 to a larger extent in the semiconductor device 3A than in the semiconductors 1, 2A, and 2B, because the high dielectric layer 50 is arranged on the top side of the base layer 11 and the high dielectric layer 51 is arranged along the sidewall 21 and the bottom surface 22 of the STI 20. Accordingly, the ON resistance per a unit area is lower in the semiconductor device 3A than in the semiconductor devices 1, 2A, and 2B.

In addition, FIG. 8B shows a semiconductor device 3B as the fourth variation example.

Even in a case where the high dielectric layer 51 is arranged in at least a part in the STI 20, the above-described capacitive coupling can be facilitated. For this reason, in the semiconductor device 3B, the high dielectric layer 51 is provided along only the sidewall 21 of the STI 20. As a result, the neighboring elements can be electrically isolated from each other securely. In addition, the ON resistance per a unit area is lower in the semiconductor device 3B than in the semiconductor devices 1, 2A, and 2B.

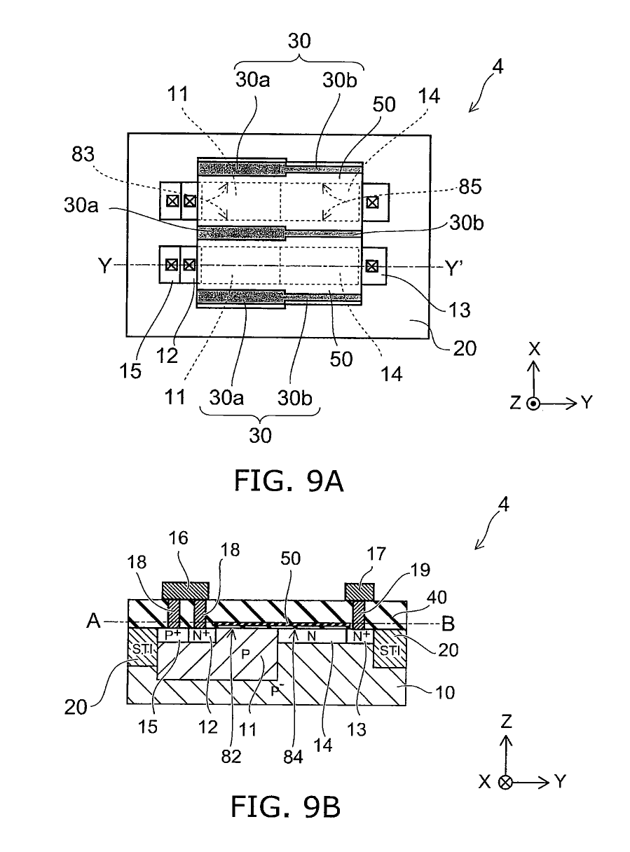

FIGS. 9A and 9B show a semiconductor device of a fifth variation example of the embodiment. FIG. 9A is a main part lateral cross-section view of the semiconductor device of the fifth variation example as taken along the A-B horizontal plane of FIG. 9B and viewed from above. FIG. 9B is a Y-Y′ cross-sectional view of FIG. 9A. However, the interlayer insulating layer 40 is excluded from FIG. 9A.

In a semiconductor device 4 as the fifth variation example, not only the high dielectric layer 50 is provided, but also a drift layer 14 of N-type is provided between the base layer 11 and the drain region 13. The high dielectric layer 50 is provided on the drift layer 14 and between the drift layer 14 and the gate electrode 30. In addition, the width of a gate electrode 30b provided in parallel with the drift layer 14 is set narrower than the width of a gate electrode 30a provided in parallel with the base layer 11. The width of the gate electrode 30 is defined as a width of the gate electrode 30 taken in the X direction.

Operations of the semiconductor device 4 will be described.

First of all, a voltage applied to the gate electrode 30 is set at a voltage not higher than a threshold value. A predetermined voltage is applied between the source region 12 and the drain region 13. In this case, in the drift layer 14, a depletion layer extends from an interface between the base layer 11 and the drift layer 14. At this time, no inversion layer is formed on the surface 82 or the sidewall 83 of the base layer 11.

In this respect, it is desirable that the resistance of the drift layer 14 is low because the drift layer 14 serves as the current flowing passage for the transistor. To realize this, there is a method in which the concentration of impurities in the drift layer 14 is simply increased. However, the simple increasing of the concentration of impurities in the draft layer 14 makes the depletion layer hard to extend in the drift layer 14, and there are some cases where the breakdown voltage cannot be maintained.

With this taken into consideration, the gate electrode 30b is arranged in parallel with the drift layer 14. An electric field is applied also between the gate electrode 30b and the drift layer 14. For this reason, in the drift layer 14, a depletion layer extends also from an interface between the drift layer 14 and the STI 20. These depletion layers are overlapped. Accordingly, in the semiconductor device 4, the depletion layers can fully extend inside the drift layer 14. As a result, the intensity of the electric field between the drain region 13 and the source region 12 is easily relaxed, and thus the concentration of the impurities in the drift layer 14 can be increased. As described above, the ON resistance can be reduced while maintaining the breakdown voltage between the drain region 13 and the source region 12.

In the semiconductor device 4, while the concentration of the impurities in the drift layer 14 is set high, the width of the gate electrode 30b provided in parallel with the drift layer 14 is set narrower than that of the gate electrode 30a. In such a structure, a predetermined voltage is applied between the gate electrode 30b and the drift layer 14 even if the concentration of the impurities in the drift layer 14 is set high. Thus, the depletion layers easily extend inside the drift layer 14.

Furthermore, in the semiconductor device 4, because the width of the gate electrode 30b is set narrower than that of the gate electrode 30a, the distance between the gate electrode 30b and the drift layer 14 is extended, and the intensity of the electric field between the gate electrode 30b and the drift layer 14 can be controlled. Thereby, avalanche breakdown less likely occurs between the gate electrode 30 and the drift layer 14, and accordingly the semiconductor device 4 maintains the high breakdown voltage.

When the voltage applied to the gate electrode 30 is set at a voltage not lower than the threshold value, the above-described inversion layer 80 is formed on the surface 82 or the sidewall 83 of the base layer 11. Thereby, a current flows between the source region 12 and the drain region 13. Furthermore, in the semiconductor device 4, because the drift layer 14 is N-type, an accumulation layer is formed on a surface 84 or a sidewall 85 of the drift layer 14. By the formation of the accumulation layer, free carriers further increase inside the drift layer 14. Accordingly, the ON resistance is much lower in the semiconductor device 4 than in the semiconductor devices 1 to 3.

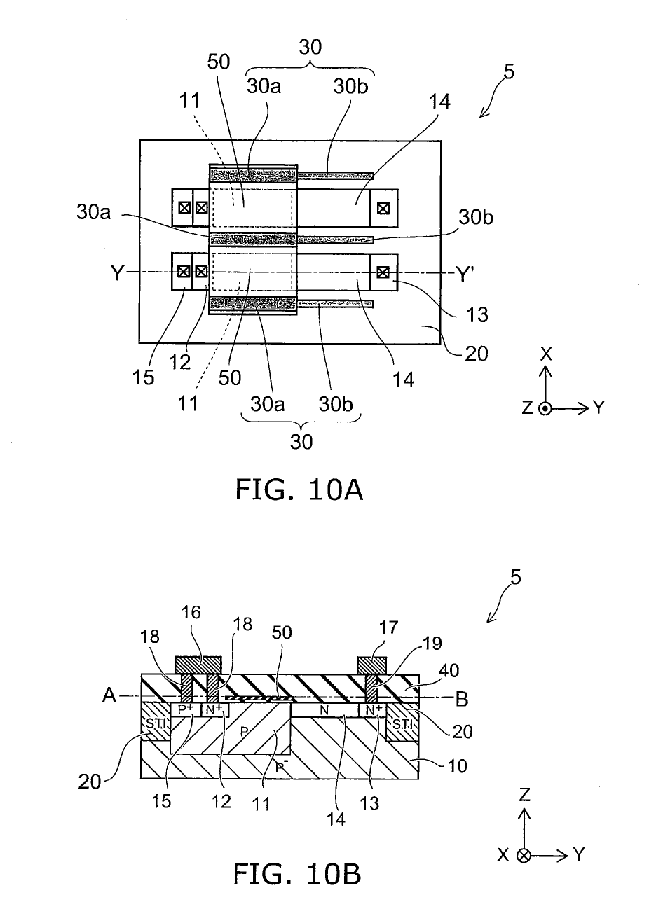

FIGS. 10A and 10B show a semiconductor device of a sixth variation example of the embodiment. FIG. 10A is a main part lateral cross-sectional view of the semiconductor device of the sixth variation example as taken along the A-B horizontal plane of FIG. 10B and viewed from above. FIG. 10B is a Y-Y′ cross-sectional view of FIG. 10A. However, the interlayer insulating layer 40 is excluded from FIG. 10A.

In a semiconductor device 5 as the sixth variation example, the high dielectric layer 50 is arranged on the top side of the base layer 11. However, no high dielectric layer 50 is provided on the drift layer 14 or between the drift layer 14 and the gate electrode 30b.

With such a structure, in the capacitance between the gate electrode 30 and the drain region 13, the capacitance between the gate electrode 30b in parallel with the drift layer 14 and the drain region 13 is much smaller. For this reason, the capacitance between the gate electrode 30 and the drain region 13 decreases. Accordingly, the Miller capacitance can be made lower in the semiconductor device 5 than in the semiconductor device 4, and the semiconductor device 5 is capable of achieving a faster switching operation than the semiconductor device 4.

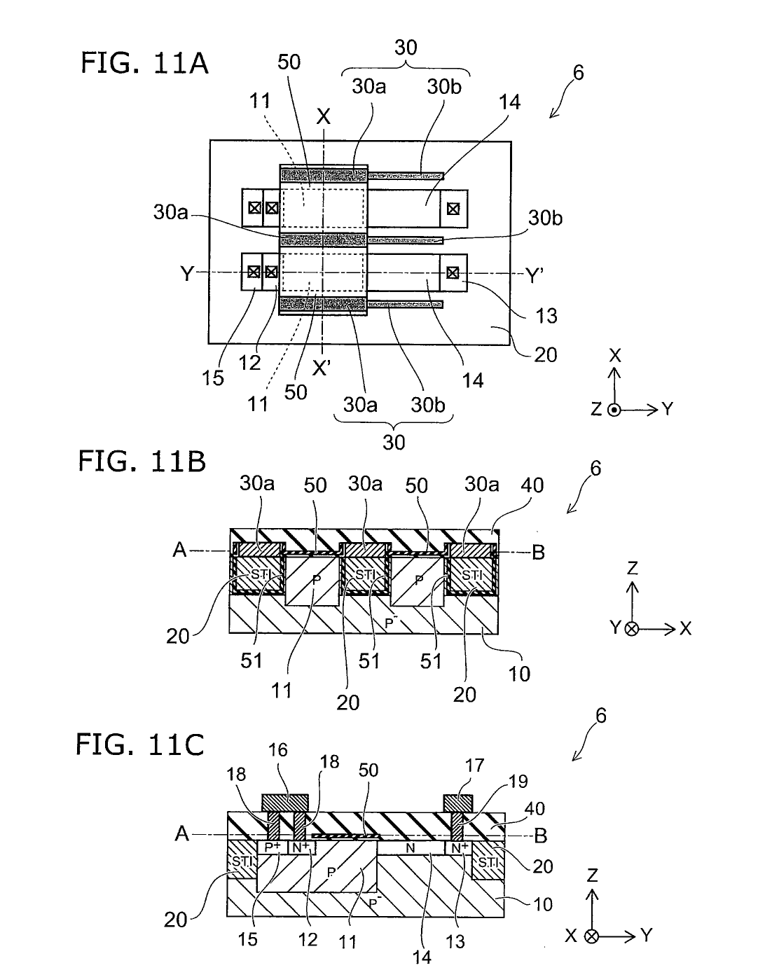

FIGS. 11A to 11C show a semiconductor device of a seventh variation example of the embodiment. FIG. 11A is a main part lateral cross-sectional view of the semiconductor device of the seventh variation example as taken along the A-B horizontal plane of FIGS. 11B and 11C and viewed from above. FIG. 11B is an X-X′ cross-sectional view of FIG. 11A. FIG. 11C is a Y-Y′ cross-sectional view of FIG. 11A. However, the interlayer insulating layer 40 is excluded from FIG. 11A.

In a semiconductor device 6 as the seventh variation example, the high dielectric layer 50 is arranged on the top side of the base layer 11. However, no high dielectric layer 50 is provided on the drift layer 14. In the semiconductor device 6, in addition to the high dielectric layer 50, the high dielectric layer 51 is provided in at least a part in the STI 20.

With such a structure, in the capacitance between the gate electrode 30 and the drain region 13 in the semiconductor device 6, the capacitance between the gate electrode 30b in parallel with the drift layer 14 and the drain region 13 is much smaller. Accordingly, the semiconductor device 6 is capable of achieving a faster switching operation than the semiconductor device 4. Furthermore, in the semiconductor device 6, because the high dielectric layer 51 is provided in at least a part in the STI 20, the density of charges in the inversion layer 80 increases. Accordingly, the semiconductor device 6 can make the ON resistance lower than the semiconductor device 5.

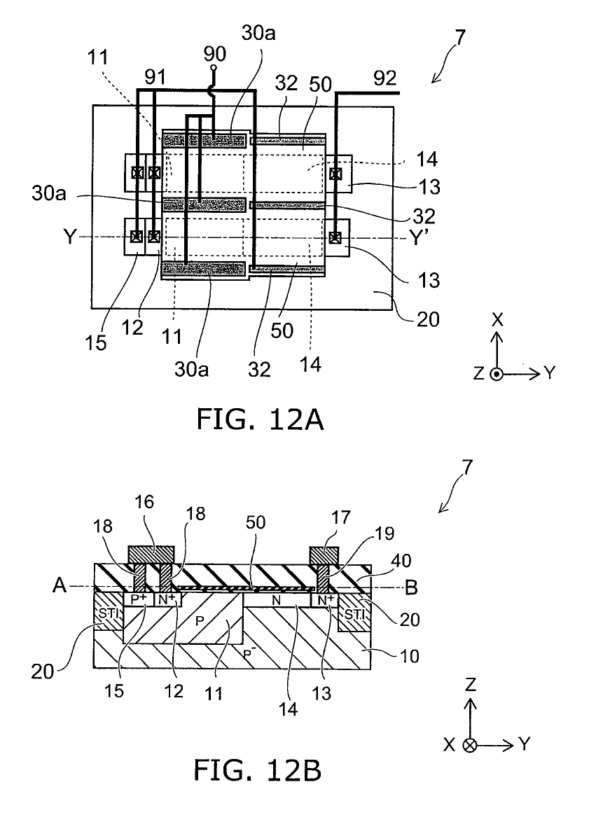

FIGS. 12 A and 12B show a semiconductor device of an eighth variation example of the embodiment. FIG. 12A is a main part lateral cross-sectional view of the semiconductor device of the eighth variation example as taken along the A-B horizontal plane of FIG. 12B and viewed from above. FIG. 12B is a Y-Y′ cross-sectional view of FIG. 12A. However, the interlayer insulating layer 40 is excluded from the FIG. 12A.

In a semiconductor device 7 as the eighth variation example, not only the high dielectric layer 50 is provided, but also a structure in which a portion of the gate electrode 30b is separated from the gate electrode 30a is included. A portion electrically independent from the gate electrode 30a is taken as an electrode 32. The electrode 32 is arranged in parallel with the drift layer 14. In addition, the gate electrodes 30a are connected together by a common line 90. The electrodes 32 are connected to the source electrodes 16 through a common line 91 and are accordingly electrically connected to the source regions 12. Furthermore, the drain regions 13 are connected together by a common line 93 through the respective drain electrodes 17.

Even in a case where a predetermined voltage is applied between the source electrode 16 and the drain electrode 17, this semiconductor device 7 makes no current flow between the source electrode 16 and the drain electrode 17 if the voltage of the gate electrode 30a is not higher than the threshold value. When the voltage of the gate electrode 30a becomes not lower than the threshold value, a current flows between the source electrode 16 and the drain electrode 17. However, an accumulation layer is less likely to be formed in the drift layer 14, because the electrode 32 is electrically conductive to the source electrode 16.

However, the capacitance between the gate electrode and the drain electrode 17 is only the capacitance between the gate electrode 30a and the drain electrode 17. For this reason, the capacitance becomes much smaller in the semiconductor device 7 than in the semiconductor devices 4 to 6. Accordingly, the Miller capacitance can be made lower in the semiconductor device 7 than in the semiconductors 4 to 6, and the semiconductor device 7 achieves a much faster switching operation.

Hereinabove, embodiments are described with reference to specific examples. However, the embodiments are not limited to these specific examples. In other words, various modifications made by those skilled in the art to these specific examples as appropriate shall fall within the scope of the embodiment as long as they include the features of the embodiments. For example, any component included in the above-described specific examples, as well as its arrangement, material, condition, shape, size and the like is not limited to what has been shown as its examples, and can be changed whenever deemed necessary.

Moreover, the foregoing descriptions have been provided for the embodiments in which the first conductivity type is defined as N-type and the second conductivity type is defined as P-type. However, a structure in which the first conductivity type is defined as P-type and the second conductivity type is defined as N-type is also included in the embodiments, and the same effects are obtained. In addition, the embodiments can be carried out by variously modifying the embodiments within the scope not departing from the gist of the embodiments.

In addition, the respective constituents included in the embodiments described above can be combined together within a technically achievable scope, and such a combination is also included in the scope of the embodiments as long as the combination includes the features of the embodiments.

Furthermore, those skilled in the art could conceive various modifications and alterations in the scope of the spirit of the embodiments. It shall be understood that such modifications and alterations pertain to the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a base layer of a second conductivity type including a source region of a first conductivity type and a drain region of the first conductivity type selectively formed on a surface of the base layer;
a device isolation layer provided in the base layer to extend in a direction from the source region to the drain region;
a control electrode provided on a top side of the device isolation layer to control a current passage between the source region and the drain region;
a high dielectric layer arranged in at least a part on a top side of the base layer or in at least a part in the device isolation layer, the high dielectric layer having a higher dielectric constant than a dielectric constant of the device isolation layer;
a first main electrode connected to the source region; and
a second main electrode connected to the drain region.

2. The device according to claim 1, wherein the high dielectric layer is arranged in at least the part on the top side of the base layer and in at least the part in the device isolation layer.

3. The device according to claim 1, wherein the high dielectric layer extends from the top of the base layer to a sidewall of the control electrode.

4. The device according to claim 3, wherein the sidewall of the control electrode is situated inside a sidewall of the device isolation layer.

5. The device according to claim 1, wherein the high dielectric layer is provided along a sidewall or a bottom surface of the device isolation layer.

6. The device according to claim 1, wherein the high dielectric layer is provided along a sidewall and a bottom surface of the device isolation layer.

7. The device according to claim 1, wherein a material of the high dielectric layer is silicon nitride (Si₃N₄) or hafnium oxide (HfO₂).

8. The device according to claim 1, further comprising a drift layer of the first conductivity type provided between the base layer and the drain region.

9. The device according to claim 8, wherein a width of the control electrode in parallel with the drift layer is narrower than a width of the control electrode in parallel with the base layer.

10. The device according to claim 8, wherein the high dielectric layer is not provided on a top side of the drift layer.

11. The device according to claim 8, wherein the high dielectric layer is not provided between the drift layer and the control electrode.

12. The device according to claim 8, wherein
a portion of the control electrode in parallel with the drift layer is separated from the control electrode in parallel with the base layer, and
the portion is electrically connected to the first main electrode.

13. The device according to claim 1, wherein the device isolation layer is periodically arranged in a direction almost perpendicular to the direction from the source region to the drain region.

14. A DC-DC converter comprising:
a high-side switching element;
a low-side switching element connected to the high-side switching element in series;
a semiconductor device serving as a driver circuit for controlling the high-side switching element and the low-side switching element, the semiconductor device including: a base layer of a second conductivity type including a source region of a first conductivity type and a drain region of the first conductivity type selectively formed on a surface of the base layer; a device isolation layer provided in the base layer to extend in a direction from the source region to the drain region; a control electrode provided on a top side of the device isolation layer to control a current passage between the source region and the drain region;
a high dielectric layer arranged in at least a part on a top side of the base layer or in at least a part in the device isolation layer, the high dielectric layer having a higher dielectric constant than a dielectric constant of the device isolation layer; a first main electrode connected to the source region; and a second main electrode connected to the drain region;
an inductor having one end side connected between the high-side switching element and the low-side switching element; and,
a capacitor connected to one other end side of the inductor.

15. The converter according to claim 14, wherein the semiconductor device and the control circuit for controlling the semiconductor device are provided on a same substrate.
